(19) United States
(12) Patent Application Publication
(10) Pub. No.: US 2026/0013115 A1
(43) Pub. Date: Jan. 8, 2026

(54) SEMICONDUCTOR DEVICE AND MANUFACTURE METHOD THEREOF

(71) Applicant: NANYA TECHNOLOGY CORPORATION, New Taipei City (TW)

(72) Inventor: Wei-Chuan FANG, New Taipei City (TW)

(21) Appl. No.: 18/764,116

(22) Filed: Jul. 3, 2024

(51) Int. Cl. H10B 12/00

(52) U.S. Cl. CPC H10B 12/482; H10B 12/02

(57) ABSTRACT

A semiconductor device is provided, including: a substrate, a unit structure, a first spacer structure, a second spacer structure, a bit line structure, a landing pad and a protective layer. The unit structure includes a first unit structure and a second unit structure, and the bit line structure is spaced apart from the first unit structure by the first spacer structure and is spaced apart from the second unit structure by the second spacer structure, in which the first spacer structure includes a first spacer nitride layer and a first air gap formed in the first spacer nitride layer. A protective layer seals the first air gap, in which a weight percentage of carbon in the protective layer is from 4.2% to 50%. A method of manufacturing a semiconductor device is further provided.

### BACKGROUND

### FIELD OF INVENTION

The present disclosure relates to a semiconductor device and a method of manufacturing a semiconductor device.

### DESCRIPTION OF RELATED ART

Semiconductor devices are widely used in the electronics industry since semiconductor devices have relatively small size, multifunctional properties, and relatively low manufacturing costs, in which air gaps (AGs) are commonly applied in semiconductor devices for reducing parasitic capacitance and resistance. However, since the size of the semiconductor device shrinks and the aspect ratio of the air gap increases, the difficulty in sealing AGs increases, causing the rise of current leakage.

For the foregoing reason, there is a need to solve the above-mentioned problem by providing a semiconductor device for reducing the current leakage.

### SUMMARY

Some embodiments of the present disclosure provide a semiconductor device, including: a substrate, a unit structure, a first spacer structure, a second spacer structure, a bit line structure, a landing pad and a protective layer. A substrate includes an unit area and a peripheral area. A unit structure, a first spacer structure, a second spacer structure and a bit line structure are on the unit area, in which the unit structure includes a first unit structure and a second unit structure, and the bit line structure is spaced apart from the first unit structure by the first spacer structure and is spaced apart from the second unit structure by the second spacer structure, in which the first spacer structure includes a first spacer nitride layer and a first air gap formed in the first spacer nitride layer. A landing pad is disposed on the unit structure, the second spacer structure and the bit line structure. A protective layer seals the first air gap, in which a weight percentage of carbon in the protective layer is from 4.2% to 50% based on 100% by weight percentage of the protective layer.

In some embodiments, the second spacer structure includes a second spacer nitride layer and a second air gap embedded in the second spacer nitride layer.

In some embodiments, the landing pad covers the second air gap.

In some embodiments, the semiconductor device further includes a barrier layer between the unit structure and the landing pad.

In some embodiments, the protective layer is disposed on the barrier layer.

In some embodiments, the protective layer conformally covers a side wall of the landing pad, a top surface of the first spacer structure and a side wall of the bit line structure.

In some embodiments, in a cross-sectional view, the protective layer on the side wall of the landing pad, on the top surface of the first spacer structure and on the side wall of the bit line structure defines a recess.

In some embodiments, a top surface of the protective layer is coplanar with or lower than a top surface of the landing pad.

In some embodiments, a weight ratio of silicon and nitrogen in the protective layer is from 0.5:1 to 2:1.

In some embodiments, the first air gap is surrounded and sealed by the protective layer and the first spacer nitride layer.

Some embodiments of the present disclosure provide a method of manufacturing a semiconductor device, including: providing a substrate, including an unit area and a peripheral area; forming a unit structure, a first spacer structure, a second spacer structure, and a bit line structure on the unit area, in which the unit structure includes a first unit structure and a second unit structure, and the bit line structure is spaced apart from the first unit structure by the first spacer structure and is spaced apart from the second unit structure by the second spacer structure, in which the first spacer structure includes a first spacer nitride layer and a first spacer sacrificial layer embedded in the first spacer nitride layer; depositing a landing pad on the unit structure, the second spacer structure and the bit line structure; removing the first spacer sacrificial layer to form a first air gap; and depositing a protective layer to seal the first air gap, in which a weight percentage of carbon in the protective layer is from 4.2% to 50% based on 100% by weight percentage of the protective layer.

In some embodiments, the step of forming the unit structure, the first spacer structure, the second spacer structure, and the bit line structure on the unit area includes forming a barrier layer on the unit structure and directly contacting the first spacer structure and the second spacer structure.

In some embodiments, the second spacer structure includes a second spacer nitride layer and a second spacer sacrificial layer embedded in the second spacer nitride layer, and the step of removing the first spacer sacrificial layer includes removing the second spacer sacrificial layer to form a second air gap.

In some embodiments, the step of depositing the landing pad on the unit structure, the second spacer structure and the bit line structure includes: depositing a landing pad layer on the unit structure, the first spacer structure, the second spacer structure and the bit line structure; and removing a portion of the first spacer structure, a portion of the bit line structure and a portion of the landing pad layer to form the landing pad.

In some embodiments, the step of removing the first spacer sacrificial layer includes forming the first air gap exposed to an outside.

In some embodiments, a weight ratio of silicon and nitrogen in the protective layer is from 0.5:1 to 2:1.

In some embodiments, depositing the protective layer is performed at a temperature of from 500°C to 700°C.

In some embodiments, depositing the protective layer is performed at a deposition rate of from 10Ǻ/s to 20Ǻ/s.

In some embodiments, the protective layer conformally covers the landing pad, the first spacer structure and the bit line structure.

In some embodiments, the method further includes removing a portion of the protective layer on the landing pad.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 is a flow diagram illustrating a method of manufacturing a semiconductor device in accordance with some embodiments.

FIGS. 2A-2F are cross-sectional views of various intermediary stages in the manufacturing of a semiconductor device in accordance with some embodiments of this disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

The terminology used herein is for the purpose of describing particular example embodiments only and is not intended to be limiting of the present disclosure. Single forms used in the present specification such as “a”, “one” and “the” includes multiple forms such as “at least one”; “or” represents “and/or” unless described clearly. As used herein, the term “and/or” includes any and all combinations of one or more of the associated listed items. It will be further understood that the terms "comprises", "comprising", and/or “has”, “have”, “having” when used in this specification, specify the presence of stated features, areas, integers, steps, operations, elements, and/or components, but do not preclude the presence or addition of one or more other features, areas, integers, steps, operations, elements, components, and/or groups thereof.

Embodiments of the present disclosure are described herein with reference to top illustrations that are schematic illustrations of idealized embodiments of the present disclosure. As such, variations from the shapes of the illustrations as a result, for example, of manufacturing techniques and/or tolerances, are to be expected. Thus, embodiments of the present disclosure should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present disclosure.

Reference will now be made in detail to embodiments of the present disclosure, examples of which are described herein and illustrated in the accompanying drawings. While the disclosure will be described in conjunction with embodiments, it will be understood that they are not intended to limit the disclosure to these embodiments. Therefore, the scope of the present disclosure is to be limited only by the appended claims.

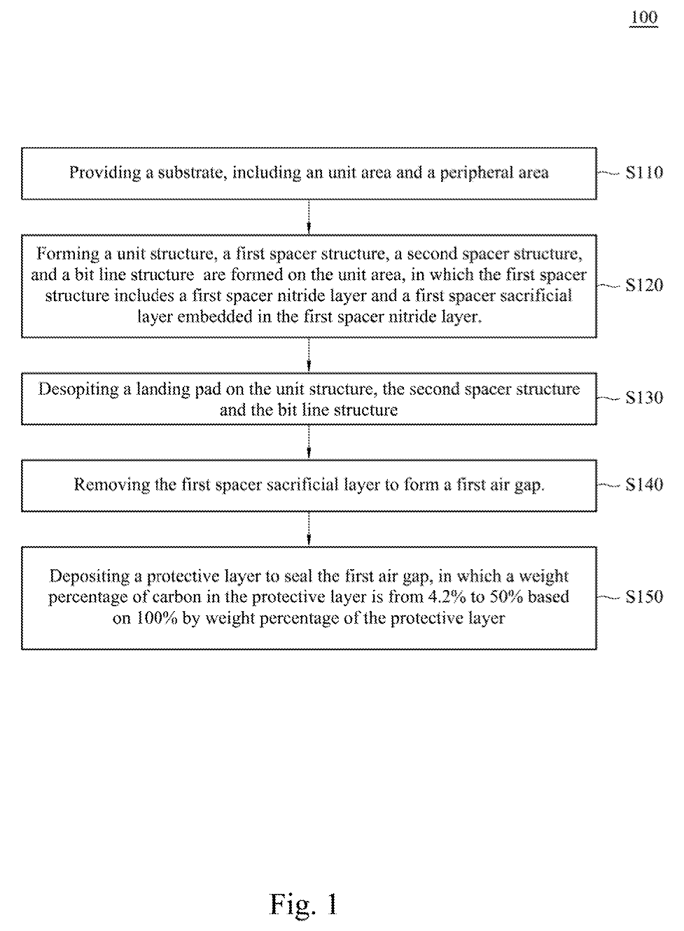

Referring to FIG. 1, illustrating a method 100 of manufacturing a semiconductor device, and the method 100 includes steps S110, S120, S130, S140 and S150. The steps S110 to S150 of FIG. 1 are elaborated in connection with following figures, providing a semiconductor device which reduces the risk of current leakage and decreases parasitic capacitance and resistance by providing a protective layer with higher etching resistivity.

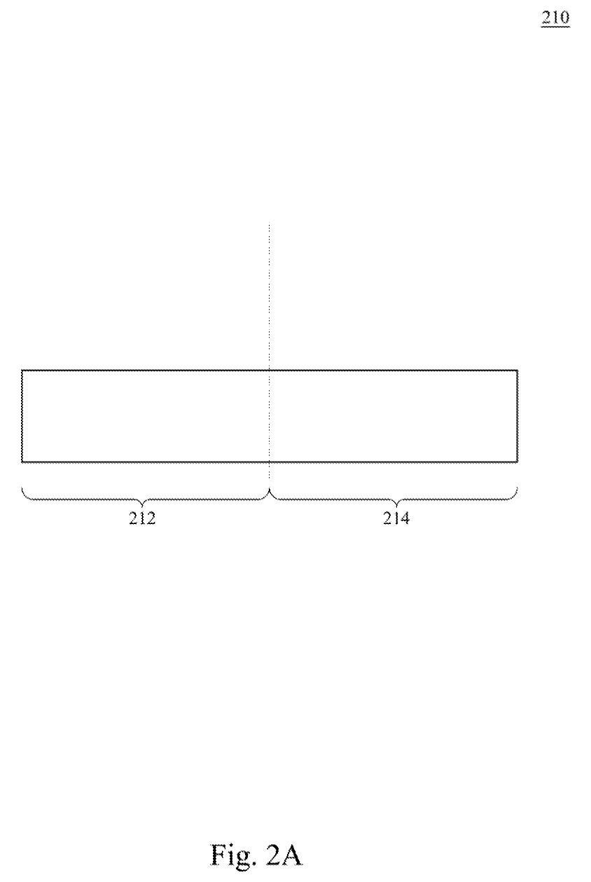

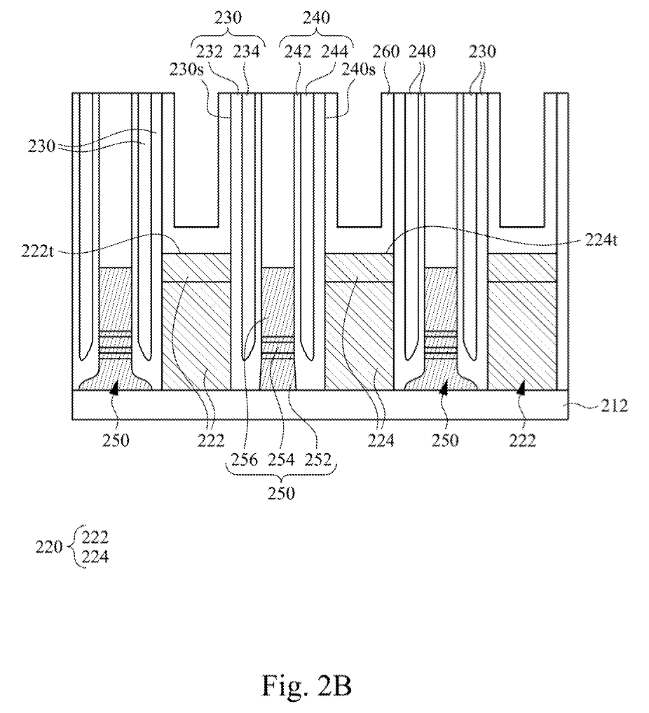

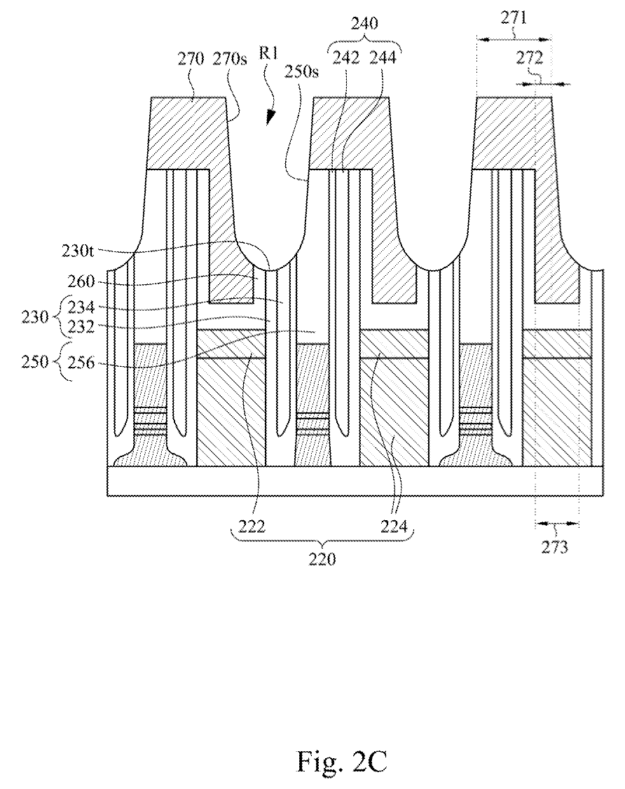

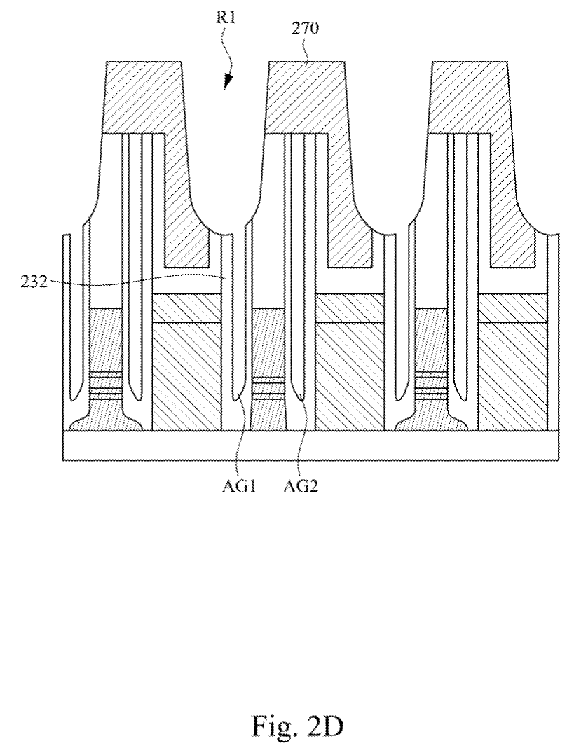

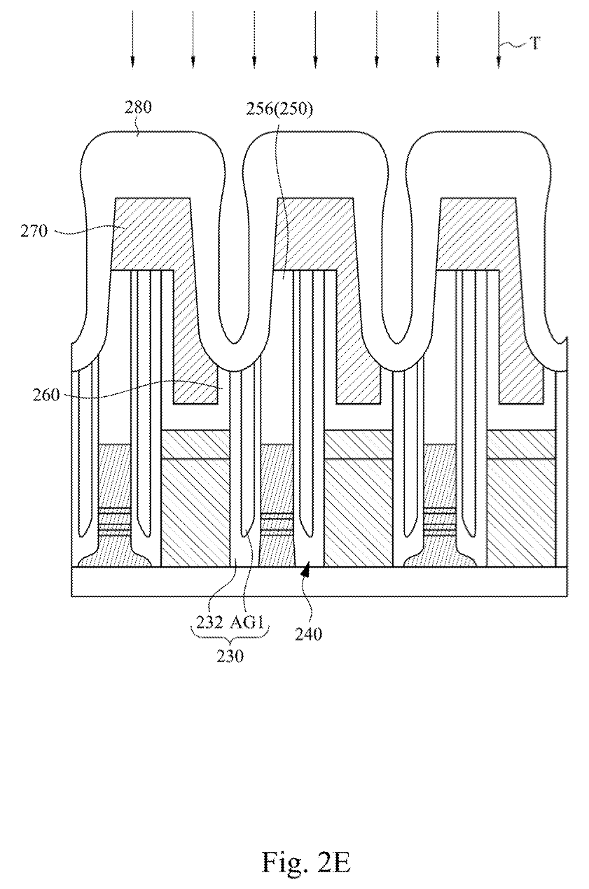

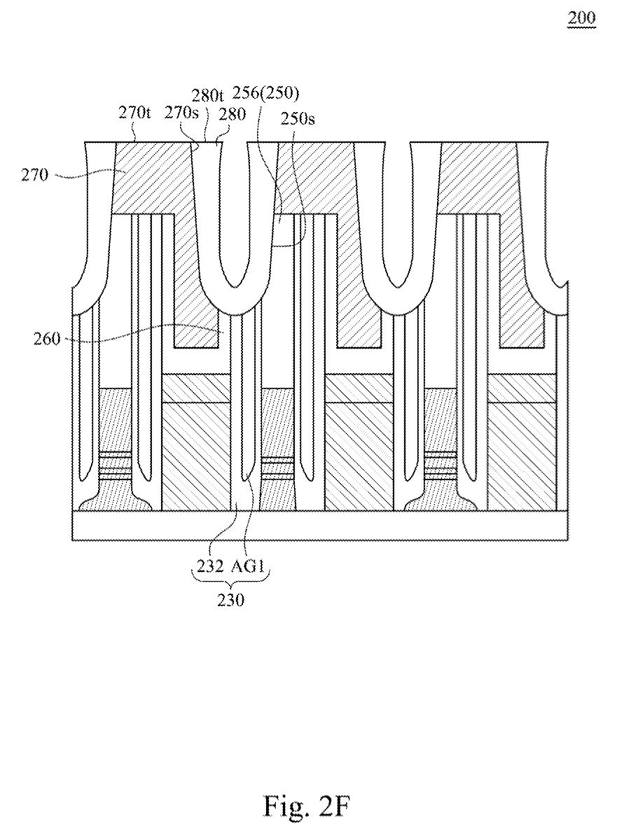

Referring to step S110 of FIG. 1 and FIG. 2A, a substrate 210 is provided, including a unit area 212 and a peripheral area 214.

In some embodiments, the substrate 210 includes a base material or structure on which materials are formed. In some embodiments, the substrate 210 may include a single material, multiple layers of different materials, one or more layers having regions of different materials or different structures therein, or other similar configurations. These materials may include semiconductors, insulators, conductors, or combinations thereof. In some embodiments, the substrate 210 may be a silicon substrate, a GaAs substrate, a SiGe substrate, a ceramic substrate, a quartz substrate, a glass substrate, a silicon on insulator (SOI) substrate, or the like. In some embodiments, the substrate 210 may include compound semiconductors (such as SiC, GaAs, GaP, InP, InAs or InSb) or alloy semiconductors (such as SiGe, GaAsP, AlInAs, AlGaAs, GaInAs, GaInP, or GaInAsP). In some embodiments, the substrate 210 includes a metal layer. In some embodiments, the substrate 210 is a multi-layer structure, including a polysilicon layer and a metal layer sequentially stacked on the polysilicon layer.

Referring to step S120 of FIG. 1 and FIG. 2B, a unit structure 220, a first spacer structure 230, a second spacer structure 240, and a bit line structure 250 are formed on the unit area 212, in which the first spacer structure 230 includes a first spacer nitride layer 232 and a first spacer sacrificial layer 234 embedded in the first spacer nitride layer 232.

In some embodiments, the unit structure 220 includes a first unit structure 222 and a second unit structure 224, and the bit line structure 250 is spaced apart from the first unit structure 222 by the first spacer structure 230 and is spaced apart from the second unit structure 224 by the second spacer structure 240.

In some embodiments, the bit line structure 250 is sandwiched between the first spacer structure 230 and the second spacer structure 240. In some embodiments, the bit line structure 250 directly contacts the first spacer structure 230 and the second spacer structure 240, and the first spacer structure 230 and the second spacer structure 240 directly contacts the first unit structure 222 and the second unit structure 224, respectively. That is, the first unit structure 222 and the second unit structure 224 are located on the opposite sides of the bit line structure 250, respectively, in which the first spacer structure 230 is located between the first unit structure 222 and the bit line structure 250, and the second spacer structure 240 is located between the second unit structure 224 and the bit line structure 250.

In some embodiments, the first unit structure 222 includes conductive materials for serving as cell contacts. In some embodiments, the first unit structure 222 includes multiple layers of conductive materials (such as Cu, Sn, Al, W, Ag, or the like) stacked with each other. In some embodiments, the materials and structures of the second unit structure 224 is similar to which of the first unit structure 222.

In some embodiments, similar to the first spacer structure 230, the second spacer structure 240 includes a second spacer nitride layer 242 and a second spacer sacrificial layer 244 embedded in the second spacer nitride layer 242, in which the second spacer nitride layer 242 and the second spacer sacrificial layer 244 have different etching selectivity ratios. In some embodiments, since the first spacer sacrificial layer 234 and the second spacer sacrificial layer 244 are embedded, the first spacer structure 230 directly contacts the first unit structure 222 and the bit line structure 250 by the first spacer nitride layer 232, and the second spacer structure 240 directly contacts the second unit structure 224 and the bit line structure 250 by the second spacer nitride layer 242.

In some embodiments, the first spacer nitride layer 232 and the first spacer sacrificial layer 234 have different etching selectivity ratios. For example, the first spacer nitride layer 232 includes nitrides (such as SiN), and the first spacer sacrificial layer 234 includes oxides (such as SiOx). In some embodiments, the materials of the second spacer nitride layer 242 is similar to which of the first spacer nitride layer 232, and the materials of the second spacer sacrificial layer 244 is similar to which of the first spacer sacrificial layer 234.

In some embodiments, the bit line structure 250 includes a bit line contact 252, a bit line metal layer 254, and a bit line nitride 256 from bottom to top and stacked with each other. In some embodiments, the bit line contact 252 and the bit line metal layer 254 includes conductive material different from each other. For example, the material of the bit line contact 252 includes Cu, and which of the bit line metal layer 254 includes W. In some embodiments, the bit line nitride 256 includes nitrides, such as SiN.

In some embodiments, step S120 includes forming a barrier layer 260 on the unit structure 220 and directly contacting the first spacer structure 230 and the second spacer structure 240. In some embodiments, the barrier layer 260 conformally covers a side wall 230s of the first spacer structure 230, a top surface 222t of the first unit structure 222, or conformally covers a side wall 240s of the second spacer structure 240 and a top surface 224t of the second unit structure 224. In some embodiments, the barrier layer 260 may include silicon oxide, silicon oxynitride, silicon nitride, or the like, for separating the top surface 222t or the top surface 224t from the layers manufactured in the following steps to avoid current interference.

Referring to step S130 of FIG. 1 and FIG. 2C, a landing pad 270 is deposited on the unit structure 220, the second spacer structure 240 and the bit line structure 250.

In some embodiments, the step S130 includes depositing a landing pad layer (not shown in FIG. 2C) on the unit structure 220, the first spacer structure 230, the second spacer structure 240 and the bit line structure 250; and removing a portion of the first spacer structure 230, a portion of the bit line structure 250 and a portion of the landing pad layer on the abovementioned elements (the first spacer structure 230 and the bit line structure 250) to form the landing pad 270.

In some embodiments, the first spacer nitride layer 232, the first spacer sacrificial layer 234, the bit line nitride 256, and the portion of the bit line structure 250 on the abovementioned elements are removed, and a side wall 270s of the landing pad 270, a top surface 230t of the first spacer structure 230 and a side wall 250s of the bit line structure 250 (that is, a side wall of the bit line nitride 256) defines a recess R1 together. In some embodiments, in the cross-sectional view, the landing pad 270 is wider at top (top portion 271), narrow at bottom (bottom portion 273) and most narrow in the middle (middle portion 272).

In some embodiments, the landing pad layer is also disposed on the barrier layer 260 in the step of depositing the landing pad layer (not shown in FIG. 2C) and then a portion of the barrier layer 260 (not shown in FIG. 2C) is removed while removing the portion of the first spacer structure 230, the portion of the bit line structure 250 and the portion of the landing pad layer on the abovementioned elements. Since the first unit structure 222 is embedded below the barrier layer and the landing pad layer on the second spacer structure 240 keeps intact, the first unit structure 222 and the second spacer structure 240 remain intact, and the barrier layer 260 is between the first unit structure 222 and the landing pad 270.

In some embodiments, the landing pad layer is deposited by using atomic layer deposition (ALD), atomic layer epitaxy (ALE), atomic layer chemical vapor deposition (ALCVD), spin coating, sputtering or similar processes. In some embodiments, the material of the landing pad 270 includes a conductive material, such as metal.

Referring to step S140 of FIG. 1, FIG. 2C and FIG. 2D, the first spacer sacrificial layer 234 is removed to form a first air gap AG1.

In some embodiments, the term “air gap” is used to provide a space which may be filled with air, with a gas other than air or in particular with an inert gas, such as argon, or which may be a vacuum.

In some embodiments, the first spacer sacrificial layer 234 is removed completely, and the first air gap AG1 is exposed to an outside and surrounded by the first spacer nitride layer 232. In some embodiments, the first spacer sacrificial layer 234 is removed completely. That is, the first spacer sacrificial layer 234 is completely replaced by the first air gap AG1. In some embodiments, the first spacer sacrificial layer 234 is removed by using dry etching process (such as etching by HF gas) or post-reactive ion etching (RIE) process.

In some embodiments, step S140 includes removing the second spacer sacrificial layer 244 to form a second air gap AG2 by the process similar to the formation process of the first air gap AG1. In some embodiments, the second spacer sacrificial layer 244 is removed completely. That is, the second spacer sacrificial layer 244 is completely replaced by the second air gap AG2, and the second air gap AG2 is covered by the landing pad 270.

It’s noted that the first air gap AG1 and the second air gap AG2 are formed for decreasing parasitic capacitance and resistance. Therefore, the less the first spacer sacrificial layer 234 and the second spacer sacrificial layer 244 remain, the lower parasitic capacitance and resistance the semiconductor device (final product) performs.

Referring to step S150 of FIG. 1 and FIG. 2E, a protective layer 280 is deposited to seal the first air gap AG1, in which a weight percentage of carbon in the protective layer 280 is from 4.2% to 50% based on 100% by weight percentage of the protective layer 280.

It should be noted that by controlling the weight percentage of carbon of higher than 4.2%, the protective layer 280 performs better etching resistivity, which protects the landing pad 270 from etching in the following procedures and protects the first air gap AG1 from substance from outside. Therefore, the protective layer 280 with better etching resistivity can prevent the landing pad 270 from rounding by covering the landing pad 270 and provide the semiconductor device with the lower parasitic capacitance and resistance and reduced current leakage by sealing the first air gap AG1 much securely. In some embodiments, the first air gap AG1 is surrounded and sealed by the protective layer 280 and the first spacer nitride layer 232. Specifically, the first air gap AG1 is surrounded by the first spacer nitride layer 232 and sealed by the protective layer 280.

In some embodiments, the protective layer 280 conformally covers the recess R1 (refer to FIG. 2D). In some embodiments, the protective layer 280 conformally covers the landing pad 270 (the side wall 270s of the landing pad 270, FIG. 2C), the first spacer structure 230 (the top surface 230t of the first spacer structure 230), the bit line structure 250 (the side wall 250s of the bit line structure 250) and the barrier layer 260, in which the protective layer 280 on the protective layer 280 on the side wall 270s of the landing pad 270, on the top surface 230t of the first spacer structure 230 and on the side wall 250s of the bit line structure 250 defines a recess, and the second spacer structure 240 is spaced apart from the protective layer 280 by the landing pad 270. Therefore, the landing pad 270, the first spacer structure 230, the bit line structure 250 and the barrier layer 260 are sealed and not exposed to the outside.

In some embodiments, the weight percentage of carbon in the protective layer 280 is 4.2%, 4.5%, 5%. 10%, 20%, 30%, 40%, 50%, or a value within any interval defined by the above values. It the weight percentage is too low, the etching resistivity of the protective layer 280 is not enough for protecting the landing pad 270 and the first air gap AG1 in the following procedures. If the weight percentage is too high, the electrical property is reduced since the content of other semiconductor elements is reduced.

In some embodiments, a weight ratio of silicon and nitrogen in the protective layer 280 is from 0.5:1 to 2:1, such as 0.5:1, 1:1, 1.5:1, 2:1, or a value within any interval defined by the above values. It the weight percentage is too low or too high, the electrical property is reduced.

In some embodiments, the protective layer 280 is deposited through treatment T by using ALD, ALE, ALCVD, spin coating, sputtering or similar processes. In some embodiments, depositing the protective layer 280 is performed by ALD at a temperature of higher than 500°C. It should be noted that the higher the temperature performed in ALD, the slower the deposition rate performed in ALD, which increase the etching resistivity of the protective layer 280. For example, the temperature is from 500°C to 700°C, such as 500°C, 550°C, 600°C, 650°C, 700°C, or a value within any interval defined by the above values. In some embodiments, depositing the protective layer 280 is performed at a deposition rate of from 10Ǻ/s to 20Ǻ/s, such as 10Ǻ/s, 15Ǻ/s, 20Ǻ/s, or a value within any interval defined by the above values. It the temperature is too high or the deposition rate is too slow, the velocity for forming the protective layer 280 is too slow, thereby reducing the manufacture speed. If the temperature is too low or the deposition rate is too quick, the etching resistivity of the protective layer 280 is limited and the protective efficiency is reduced.

In some embodiments, please refer to FIG. 2F, the method 100 further includes removing a portion of the protective layer 280 on the landing pad 270 to form a semiconductor device 200. Specifically, the portion of the protective layer 280 on a top surface 270t of the landing pad 270 is removed, and another portion of the protective layer 280 on the side wall 270s of the landing pad 270, the barrier layer 260, the first spacer structure 230 (the first spacer nitride layer 232 and the first air gap AG1) and the side wall 250s of the bit line structure 250 (the bit line nitride 256) is remained. It should be noted that the protective layer 280 keeps covering the side wall 270s of the landing pad 270 and sealing the first air gap AG1 since the protective layer 280 has the better etching resistivity, which can prevent the landing pad 270 from over-etching (thereby avoiding corner rounding) and prevent the first air gap AG1 from substance from outside, thereby enhancing the electrical property of the semiconductor device 200. In some embodiments, a top surface 280t of the protective layer 280 is coplanar with (FIG. 2F) or lower than (not shown in FIG. 2F) the top surface 270t of the landing pad 270.

In some embodiments, removing the portion of the protective layer 280 is performed by chemical mechanical polishing (CMP) or dry etching (such as anisotropic etching).

Some embodiments of the present disclosure provide a semiconductor device and a method of manufacturing the semiconductor device. The semiconductor device includes a protective layer with carbon of from 4.2% to 50%, which provides better etching resistivity and performs the better protective efficiency on the landing pad and the air gap, thereby enhancing the electrical property of the semiconductor device (reduction of current leakage, parasitic capacitance and resistance).

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A semiconductor device, comprising:
a substrate, including an unit area and a peripheral area;
a unit structure, a first spacer structure, a second spacer structure and a bit line structure on the unit area, wherein the unit structure comprises a first unit structure and a second unit structure, and the bit line structure is spaced apart from the first unit structure by the first spacer structure and is spaced apart from the second unit structure by the second spacer structure, wherein the first spacer structure comprises a first spacer nitride layer and a first air gap formed in the first spacer nitride layer,
a landing pad disposed on the unit structure, the second spacer structure and the bit line structure; and
a protective layer sealing the first air gap, wherein a weight percentage of carbon in the protective layer is from 4.2% to 50% based on 100% by weight percentage of the protective layer.

2. The semiconductor device of claim 1, wherein the second spacer structure includes a second spacer nitride layer and a second air gap embedded in the second spacer nitride layer.

3. The semiconductor device of claim 2, wherein the landing pad covers the second air gap.

4. The semiconductor device of claim 1, further comprising a barrier layer between the unit structure and the landing pad.

5. The semiconductor device of claim 4, wherein the protective layer is disposed on the barrier layer.

6. The semiconductor device of claim 1, wherein the protective layer conformally covers a side wall of the landing pad, a top surface of the first spacer structure and a side wall of the bit line structure.

7. The semiconductor device of claim 6, wherein in a cross-sectional view, the protective layer on the side wall of the landing pad, on the top surface of the first spacer structure and on the side wall of the bit line structure defines a recess.

8. The semiconductor device of claim 1, wherein a top surface of the protective layer is coplanar with or lower than a top surface of the landing pad.

9. The semiconductor device of claim 1, wherein a weight ratio of silicon and nitrogen in the protective layer is from 0.0-5. to 0-5..

10. The semiconductor device of claim 1, wherein the first air gap is surrounded and sealed by the protective layer and the first spacer nitride layer.

11. A method of manufacturing a semiconductor device, comprising:
providing a substrate, including an unit area and a peripheral area;
forming a unit structure, a first spacer structure, a second spacer structure, and a bit line structure on the unit area,
wherein the unit structure comprises a first unit structure and a second unit structure, and the bit line structure is spaced apart from the first unit structure by the first spacer structure and is spaced apart from the second unit structure by the second spacer structure,
wherein the first spacer structure includes a first spacer nitride layer and a first spacer sacrificial layer embedded in the first spacer nitride layer;
depositing a landing pad on the unit structure, the second spacer structure and the bit line structure;
removing the first spacer sacrificial layer to form a first air gap; and
depositing a protective layer to seal the first air gap, wherein a weight percentage of carbon in the protective layer is from 4.2% to 50% based on 100% by weight percentage of the protective layer.

12. The method of claim 11, wherein the step of forming the unit structure, the first spacer structure, the second spacer structure, and the bit line structure on the unit area comprises forming a barrier layer on the unit structure and directly contacting the first spacer structure and the second spacer structure.

13. The method of claim 11, wherein the second spacer structure includes a second spacer nitride layer and a second spacer sacrificial layer embedded in the second spacer nitride layer, and the step of removing the first spacer sacrificial layer comprises removing the second spacer sacrificial layer to form a second air gap.

14. The method of claim 11, wherein the step of depositing the landing pad on the unit structure, the second spacer structure and the bit line structure comprises:
depositing a landing pad layer on the unit structure, the first spacer structure, the second spacer structure and the bit line structure; and
removing a portion of the first spacer structure, a portion of the bit line structure and a portion of the landing pad layer to form the landing pad.

15. The method of claim 11, wherein the step of removing the first spacer sacrificial layer comprises forming the first air gap exposed to an outside.

16. The method of claim 11, wherein a weight ratio of silicon and nitrogen in the protective layer is from 0.0-5. to 0-5..

17. The method of claim 11, wherein depositing the protective layer is performed at a temperature of from 500°C to 700°C.

18. The method of claim 11, wherein depositing the protective layer is performed at a deposition rate of from 10Ǻ/s to 20Ǻ/s.

19. The method of claim 11, wherein the protective layer conformally covers the landing pad, the first spacer structure and the bit line structure.

20. The method of claim 11, further comprising removing a portion of the protective layer on the landing pad.
